(19) United States
(12) Patent Application Publication
(10) Pub. No.: US 2024/0027495 A1
(43) Pub. Date: Jan. 25, 2024

(54) CONTACT PROBE FOR PROBE HEADS OF ELECTRONIC DEVICES AND CORRESPONDING PROBE HEAD

(71) Applicant: TECHNOPROBE S.P.A., Cernusco Lombardone (LC) (IT)

(72) Inventor: Riccardo VETTORI, Cernusco Lombardone (LC) (IT)

(73) Assignee: TECHNOPROBE S.P.A., Cernusco Lombardone (LC) (IT)

(21) Appl. No.: 18/254,758

(22) PCT Filed: Dec. 9, 2021
(86) PCT No.: PCT/EP2021/084896

§ 371 Date: May 26, 2023

(30) Foreign Application Priority Data
Dec. 9, 2020 (IT) 102020000030194

(51) Int. Cl. G01R 1/073; G01R 1/067

(52) U.S. Cl. CPC G01R 1/07357; G01R 1/06738; G01R 1/07371

(57) ABSTRACT

A contact probe is disclosed having a first end portion with a contact tip adapted to abut onto a contact pad of a device under test, a second end portion with a contact head adapted to abut onto a contact pad of a board of a test equipment, a probe body extended between the first and the second end portions according to a longitudinal development axis, and an elastic stopper provided in an elastic portion of the probe body arranged contiguous to the second end portion. The elastic stopper is deformable between a first working condition, in which it has a transversal diameter greater than a transversal diameter of the probe body, and a second working condition in which it has a transversal diameter corresponding to the transversal diameter of the probe body.

### TECHNICAL FIELD

The present invention refers, in the more general aspect thereof, to a contact probe for a probe head of electronic devices and the following description is made with reference to this field of application with the only purpose of simplifying the exposition thereof.

### BACKGROUND ART

As it is well known, a probe head is essentially a device adapted to electrically connect a plurality of contact pads of a microstructure, in particular an electronic device integrated on wafer, with corresponding channels of a probe equipment which carries out the functionality test thereof, in particular electrical, or generically the test.

The test carried out on integrated electronic devices is in particular useful to detect and isolate defective devices already while being produced. Usually, the probe heads are then used for the electrical test of the electronic devices integrated on wafer before cutting and assembling the same inside a chip containment package.

A probe head usually comprises various contact elements or probes made of special alloys with good electrical and mechanical properties and provided with at least one contact portion with one of the contact pads of the device under test.

A probe head of the type commonly called vertical probe head comprises a plurality of contact probes normally held by at least one pair of plates or guides which are substantially plate-shaped and parallel to each other. Said guides are provided with suitable holes for housing the probes and are placed at a certain distance from each other in order to leave a free area or an air gap for the movement and the possible deformation of the contact probes. The pair of guides particularly comprises an upper guide, which is placed nearer the test equipment connected to the probe head, and a lower guide, which is placed nearer a wafer comprising the devices under test, both guides being provided with respective guide holes within which the contact probes axially slide. In other words, the upper guide is above the lower guide according to the axis z of the local reference of the figures.

The good connection between the contact probes of the probe head and the contact pads of the device under test is guaranteed by the pressure of the probe head on the same device, wherein the contact probes, which are movable within the guide holes made in the upper and lower guides, are subjected, during said pressing contact, to a bending inside the air gap between the two guides and a sliding inside the respective guide holes.

Furthermore, the bending of the contact probes in the air gap can be assisted by a suitable configuration of the probes themselves or of the guides thereof, as schematically shown in FIG. 1, wherein the illustrated probe head is of the so-called shifted-plate type.

In such case, the probe head 10 comprises at least one pair of upper guides (upper dies), in particular a first upper guide 16 and a second upper guide 17, which are plate-shaped and parallel to each other and to a lower guide (lower die) 18, the guides being provided with respective first upper guide holes 16A, second upper guide holes 17A and lower guide holes 18A within which the contact probes 11 slide. In other known embodiments, which are not illustrated in the figures, also the lower guide is split in a lower guide and an intermediate guide, the latter being also provided with suitable guide holes for sliding the contact probes 11.

More in particular, the first upper guide 16 and the second upper guide 17 are shifted with respect to the lower guide 18, wherein the term shifted means that the centre of the respective first upper guide holes 16A, second upper guide holes 17A and lower guide holes 18A are misaligned to each other and not along a same longitudinal direction, indicated with z in the local reference of the figures, said longitudinal direction z being perpendicular to a reference plane n, corresponding to a transversal development plane of the guides. Furthermore, the first upper guide 16 and the second lower guide 17 are shifted with respect to each other. Thereby, the contact probes 11 housed in the guide holes of said first upper guide 16, second upper guide 17 and lower guide 18 are deformed with respect to a longitudinal development axis HH of the same, corresponding to the longitudinal direction z of the local reference of the figure.

Each contact probe 11 comprises a probe body 11C essentially extended along the longitudinal development axis HH, a plurality of contact probes 11 being usually arranged inside the probe head 10 with said longitudinal development axis HH arranged orthogonally to the reference plane n.

Each contact probe 11 has at least one first contact end, indicated as contact tip 11A and adapted to abut onto a contact pad 12A of a devices under test 12 made on a semiconductor wafer 13 which develops on the reference plane n and a second contact end, indicated as contact head 11B and adapted to abut onto a contact pad 14A of a connecting board 14 toward a test equipment, such as an interface board PCB or a so-called space transformer, i.e. a board PCB which is able to carry out a spatial transformation in relation to the distribution of respective contact pads made on opposite faces thereof. The terms end or tip indicate here and in the following an end portion which is not necessarily pointed. In particular, when the probe head 10 carries out the test of integrated devices, the contact tips 11A of the contact probes 11 thereof come into pressing contact on the contact pads 12A of the device to the tested 12, the probes bend and deform and the contact head 11B thereof are also in a pressing contact with the contact pads 14A of the board 14, the contact probes 11 thus carrying out the mechanical and electrical contact between the device under test and the test equipment (not represented). which the probe head 10 forms an end element of.

Suitably, the second upper guide 17, when the first upper guide 16 identifies the guide closer to the board 14, and the lower guide 18 are suitably spaced by an air gap 19 which allows to deform the contact probes 11 during operation of the probe head 10.

The deformed configuration of the contact probes 11 guarantees that the same further deform during the contact with the device under test 12, all in a same way, reducing the risk of reciprocal contact between adjacent probes. Furthermore, thanks to the deformed configuration of the contact probes 11, the respective contact tips 11A abut onto the contact pads 12A of the device under test 12 in a sloped manner with respect to the longitudinal direction z, guaranteeing a sliding of said contact tips 11A on the pads 12A and thus a surface cleaning or scrub thereof, so as to assure the correct contact, which is not only mechanical but also electrical, between the contact probes 11 and the device under test 12.

It is equally important to guarantee the correct holding of the probes inside the probe head. Mechanisms are usually provided for this purpose in order to prevent the unwanted slipping out of the contact probes 11 from the probe head 10 in both directions of the longitudinal direction z, that is upwards and downwards, considering the local reference of the figure.

In particular, the contact head 11B of each of the contact probes 11 is provided with an enlarged portion 11D, that is with a transversal diameter greater than the transversal diameter of the first upper guide holes 16A of the first upper guide 16, the term transversal diameter meaning herein and in the following a value of maximum dimensions of a section, even not circular, taken at the reference plane n. Said enlarged portion 11D allows to guarantee the abutment of the contact head 11B onto the first upper guide 16, preventing the sliding of the contact probe 11 downwards, considering the local reference of the figure, in particular without the device under test 12 onto which the probes rest during the normal operation of the probe head 10.

Furthermore, each contact probe 11 is provided with a suitable protruding element, usually indicated as a stopper 15 and provided projecting starting from a wall of the probe body 11C. In particular, thanks to the shifting of the guides, the contact probe 11, once assembled, has a first side wall 1s1 in contact with a wall of a corresponding first upper guide hole 16A of the first upper guide 16 and a second side wall 1s2 in contact with a wall of a second upper guide hole 17A of the second upper guide 17. The stopper 15 is thus provided projecting starting from the second side wall 1s2 of the contact probe 11, so as to interfere with a lower face F1 of the second upper guide 17 when the contact probe 11 moves upwards, with respect of the local reference of the figure, for example during test operations which imply great vertical displacements, or overtravel, of the contact tips 11A, preventing the movement or sliding thereof outside of the probe head 10.

In such case, the upper guide holes 16A and 17A should be dimensioned so as to guarantee the passage also of the stopper 15, the shift between the upper guides 16 and 17 anyway ensuring the positioning of the contact probe 11 with the second side wall 1s2 resting onto the second upper guide hole 17A above the stopper 15 and thus guaranteeing the contrast of the stopper 15 with the second upper guide 17 above it, ensuring the correct holding of the contact probe 11 inside the probe head 10.

This efficient method of holding the contact probes 11 by interference between the stopper 15 and one of the upper guides, which are shifted so as to bend and deform as requested the probes, is anyway not usable in the most recent high-frequency applications, for which the so-called short probes must be used, that is probes with a rod-shaped body which is limited in length and in particular with dimensions which are lower than 5000 μm in order to limit the connected auto-inductance phenomenon, which is strongly penalizing in said high-frequency applications, such term meaning applications which involve signals which are carried by the probes with frequencies higher than 1000 MHz. In such case, in fact, the reduced dimensions of the contact probes discourage or even prevent the usage of pairs of guides, in particular as upper guides.

The presence of only one upper guide in addition to only one lower guide allows to limit as much as possible the overall dimensions of the contact head and to correctly house the contact probes also with particularly reduced dimensions. However, in this case, it is not possible to correctly position a possible stopper so as to guarantee the interference with the upper guide and the holding of the contact probes inside the probe head also where there are forces which drag them upwards, also simply the force of gravity when the probe head is turned upside down with respect to the depiction of FIG. 1 and is not associated with the test equipment, that is not resting against the board 14.

The usage of single guides is preferred also in the case of contact probes of dimensions which are not particularly reduced but when the total force transfer between the contact tips and the contact heads of the probes should be guaranteed.

It is in fact well known that the force transferred within a contact probe from the tip thereof to the head thereof is reduced by the frictions due to the contact with the guides, in particular with the walls of the guide hole in which the probes slide and thus said reduction depends on the number of the guides which house the probes. Furthermore, in case of a great number of probes housed in the probe head, the transferred forces are also affected by the possible bending which the guides are subjected to due to the typical effect of the frictions with the probes, risking that the contact force is not enough at the heads of the probes and thus not to guarantee the correct connection with the board of the test equipment.

The same type of problem connected to the force transfer along the probes, and more precisely to the reduction thereof due to the frictions with the guides and the possible bending thereof, occurs also in the case of contact probes which are subjected to great overdrives, that is to great movements in the longitudinal direction z, such as in the photonic applications.

The presence of a high number of probes within pairs of guides which should be shifted further conveys an undesired transversal force on the device under test, which is sometimes able to cause even displacements of the same.

The technical problem of the present invention is thus to provide contact probes having functional and structural features such as to allow the usage thereof in probe heads with only one upper guide and only one lower guide, guaranteeing the correct mechanical and electrical connection made by the probes between a device under test and a test equipment in addition to a correct holding of the probes inside a corresponding probe head in any circumstance, overcoming the limits and inconveniences which still affect the contact probes and the probe heads made according to the prior art.

### DISCLOSURE OF INVENTION

The solution idea underlying the present invention is to provide the contact probes with an elastic stopper adapted to guarantee enough interference with a guide, in particular an upper guide, without having to increase the diameter of the guide holes which house said probes and without needing a pair of shifted guides. The elastic stopper is made so as to protrude with respect to at least one of the side walls of the probes, preferably with respect to both the side walls, so as to come into contrast with a guide above it to prevent displacements of the probes during the normal testing, maintenance and cleaning operations of the probe head which comprises them.

Based on such solution idea, the technical problem is solved by a contact probe having a first end portion which ends with a contact tip adapted to abut onto a contact pad of a device under test and a second end portion which ends with a contact head adapted to abut onto a contact pad of a board of a test equipment, as well as a probe body extended between said first end portion and said second end portion according to a longitudinal development axis, characterized in that it comprises an elastic stopper provided in an elastic portion of said probe body arranged contiguous to said second end portion, said elastic stopper being elastically deformable between a first working condition, in which it has a transversal diameter greater than a transversal diameter of said probe body, and a second working condition in which it has a transversal diameter substantially corresponding to said transversal diameter of said probe body, the term transversal diameter meaning a maximum transversal dimension of a section, even not circular, taken according to a plane orthogonal to said longitudinal development axis.

More in particular, the invention comprises the following additional and optional features, taken singularly or, if necessary, in combination.

According to an embodiment, the elastic stopper can comprise an opening which is provided in the elastic portion of the probe body and defines two opposite arms therein which are able to move close and away one another according to a transversal direction orthogonal to said longitudinal development axis.

According to another embodiment, the opening can be drop-shaped with decreasing dimensions along the elastic portion of the probe body towards the second end portion.

Furthermore, the opening can extend along the elastic portion of the probe body over a length substantially corresponding to a length of the elastic portion, preferably comprised between 100 μm and 400 μm.

The opening can also have a non-symmetrical shape adapted to define at least one arm protruding with respect to a side wall of the contact probe.

According to an embodiment, the opening can extend also at an arm which has a free end.

In particular, the free end of said arm can face a rounded portion of the probe body.

According to another embodiment, the opening can have a substantially oval shape adapted to provide a first arm and a second arm which are substantially equal, symmetrical and contiguous, protruding from opposite walls of the contact probe.

According to another embodiment, the opening can have a substantially oval shape interrupted at an arm and adapted to define a first portion therein having a first free end and a second portion having a second free end, said elastic stopper being substantially C-shaped.

According to yet another embodiment, the probe body can have a predeformed shape with a curvilinear configuration comprising a bow in rest conditions, when the contact probe is not in contact pressing onto a contact pad of a device under test, according to an arc having a value range comprised between 1° and 5°, preferably between 2° and 3°.

The contact probe can also comprise at least one further opening, which extends along the probe body, being so formed by at least one first longitudinal arm and a second longitudinal arm, substantially parallel to each other and extended along the longitudinal development axis, separated by the at least one further opening.

According to an embodiment, the contact probe can further comprise a portion with reduced section which forms a flexing neck positioned in the probe body at the first end portion.

More in particular, the contact tip can have a reduced transversal diameter, preferably equal to 20-60%, more preferably equal to 50%, of a diameter of a remaining part of the first end portion and a length according to the longitudinal development axis comprised between 300 μm and 600 μm, preferably equal to 450 μm and/or the contact head can have a reduced transversal diameter, preferably equal to 20-60%, more preferably equal to 50%, of a diameter of a remaining part of the second end portion and a length according to the longitudinal development axis comprised between 100 μm and 400 μm, preferably equal to 250 μm.

According to an embodiment, the second end portion can comprise an enlarged portion, having a transversal diameter greater than a diameter of a remaining part of the second end portion.

The contact probe can particularly have an overall longitudinal extension which varies between 2 mm and 5 mm, preferably between 3.8 mm and 4.6 mm, more preferably equal to 2.1 mm in rest conditions, that is when the contact probe does not abut onto a contact pad of a device under test.

The technical problem is also solved by a probe head for verifying the functionality of a device under test comprising a single upper guide provided with upper guide holes and a single lower guide provided with lower guide holes for housing a plurality of contact probes which are made as above indicated and comprise an elastic stopper positioned between the single upper guide and the single lower guide, near the single upper guide.

According to an embodiment, the probe head can further comprise at least one upper frame, associated with the single upper guide and provided with respective upper openings adapted to house the contact probes and at least one lower frame, associated to the single lower guide and provided with respective lower openings for housing the contact probes.

In particular, the upper openings of the upper frame can house the second end portions of the contact probes with clearance, the contact heads projecting starting therefrom towards a board of a test equipment of which the probe head forms an end element and the lower openings of the lower frame can house the first end portions of the contact probes with clearance, the contact tips projecting starting therefrom towards a device under test.

According to an embodiment, the single lower guide can have a thickness along the longitudinal development axis greater than a thickness of the single upper guide, preferably equal to 1.8-2 times the thickness of the single upper guide and the upper frame can have a thickness comparable, preferably equal to the thickness of the single lower guide and the lower frame can have a thickness comparable, preferably equal to the thickness of the single upper guide, comparable meaning that the difference between the thicknesses is ±20%.

Finally, according to a further embodiment, the thickness of the single upper guide and the thickness of the lower frame can have values which vary from 0.100 mm to 0.150 mm, preferably equal to 0.125 mm and the thickness of the single lower guide and the thickness of the upper frame can have values which vary from 0.150 mm to 0.300 mm, preferably equal to 0.254 mm.

The features and the advantages of the contact probe and of the probe head according to the invention will be apparent from the description, made here in the following, of embodiments thereof given by way of an indicative and not limiting example with reference to the attached drawings.

### BRIEF DESCRIPTION OF DRAWINGS

In such drawings:

FIG. 1 schematically shows a frontal view of a probe head made according to the prior art;

FIG. 2 schematically shows a frontal view of a contact probe made according to the present invention;

FIGS. 3A-3B, 4A-4B, 5A-5B show respective frontal views of alternative embodiments of a detail of the contact probes made according to the present invention;

FIGS. 6A-6B schematically show respective frontal views of alternative embodiments of the contact probe according to the present invention;

FIGS. 7A-7C schematically show respective frontal views of alternative embodiments of a probe head according to the present invention.

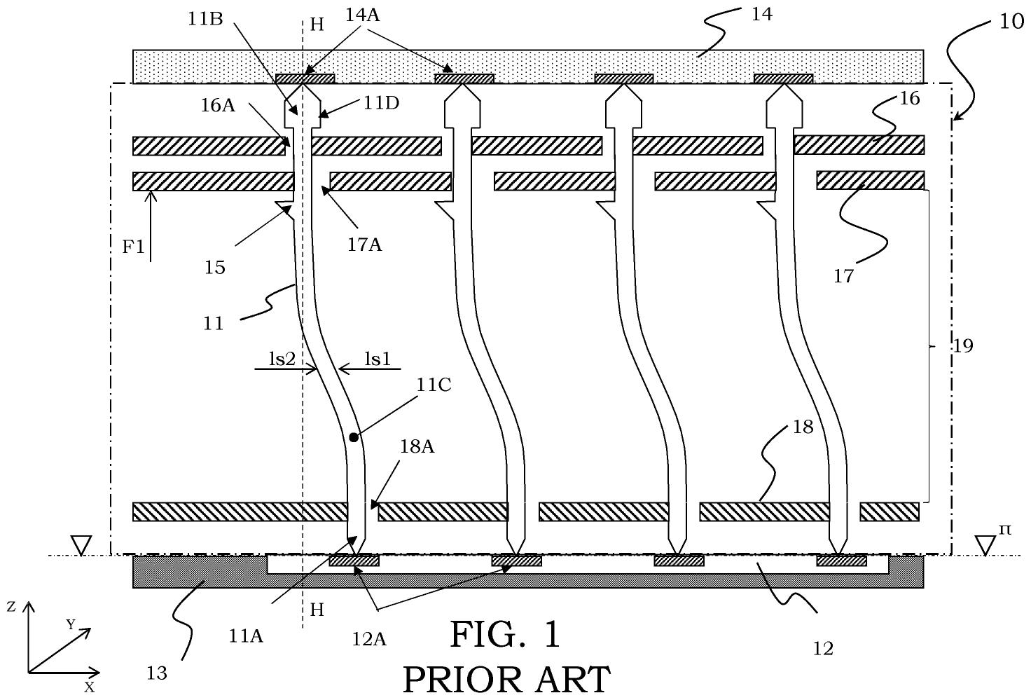

### MODES FOR CARRYING OUT THE INVENTION

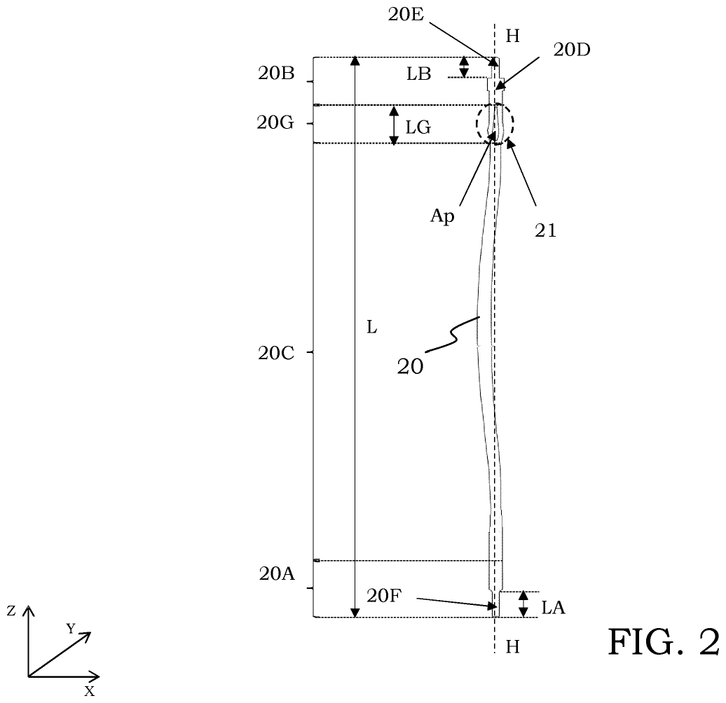

With reference to said figures, and in particular to FIG. 2, it is described a contact probe made according to the present invention, overall indicated with 20.

It is worth noting that the figures are schematic views and are not drawn to scale, but instead they are drawn so as to emphasize the important features of the invention. Moreover, in the figures, different elements are depicted in a schematic manner, and their shape may vary depending on the desired application. Furthermore, particular features illustrated in a figure in relation to an embodiment can also be used in one or more of the embodiments illustrated in the other figures.

Furthermore, structurally and functionally equal elements in the different embodiments, which are illustrated in the various figures and described, are indicated with the same alphanumeric references.

Finally, in the following description, comparative terms such as “over”, “under”, “upwards”, “downwards” will be used referring to the illustrations of the probes and probe heads given in the figures only to simplify the exposition thereof.

The contact probe 20 comprises at least one first end portion 20A which ends with a contact end adapted to abut onto a pad or contact pad of a device under test and indicated as contact tip 20F, a second end portion 20B which ends with a contact end adapted to abut onto a contact pad of a board of a test equipment and indicated as contact head 20E and a probe body 20C which is rod-shaped and extended between the end portions 20A and 20B, along a longitudinal development axis HH of the probe, substantially along the direction z of the local reference of the figure.

The contact tip 20F has a length LA according to the direction z comprised between 300 μm and 600 μm, preferably equal to 450 μm and the contact head 20E has a length LB according to the direction z comprised between 100 μm and 400 μm, preferably equal to 250 μm.

The probe body 20C preferably has a transversal diameter DC with a value which is substantially constant and equal to the diameter of the first end portion 20A and to the diameter of the second end portion 20B, said diameters being preferably equal to each other.

Suitably, according to the present invention, the probe body 20C has a predeformed shape, in the example illustrated in FIG. 2 a bow shape, that is a bow shape with the curvature change point for example at a midpoint of the probe body 20C with respect to the extension thereof along the longitudinal development axis HH. The bow shape of the contact probe 20, in particular of the probe body 20C thereof, is in particular also present in non-working conditions of the probe, that is before the same bends and deforms during the test.

The bow predeformation of the contact probes 20 guarantees that the same bend in a same desired direction, also when housed in a single upper guide which is not able to facilitate said bending direction as the double shifted guides of the known solutions. It can be verified in a simple way that it is enough to predeform the probe body 20C according to an arc having a value ranging between 1° and 5°, preferably between 2° and 3° in order to obtain the desired effect of forcing of the bending direction of the probes.

The contact probe 20 has an overall length L comprised between 2 mm and 8 mm. Such values are so when the contact probe 20 is in rest or non-working conditions, that is when it does not abut onto a contact pad of a device under test.

Preferably, for high-frequency applications, the contact probe 20 has an overall longitudinal extension L, which varies between 3 mm and 5 mm, preferably between 3.8 mm and 4.6 mm.

Such dimensional ranges for the overall extension of the contact probe 20 guarantee that the same can be used for high-frequency applications and remains elastic during the test, that it bends or compresses during the pressing contact of the contact tip thereof onto a contact pad of a device under test without plastically deforming, that is not in a definite way, so that it could be then reused.

The overall longitudinal extension L of the contact probe 20 can be furthermore reduced for particular applications which were more recently developed, down to values lower than 3 mm, preferably also lower than 2.5 mm.

Suitably according to the present invention, the contact probe 20 furthermore comprises an elastic stopper 21, made at an elastic portion of the probe body 20C arranged contiguous to the second end portion 20B and having a length LG comprised between 100 μm and 400 μm, preferably equal to 250 μm.

In the embodiment example of FIG. 2, said elastic stopper 21 is made by an opening Ap which extends along the elastic portion 20G, preferably along all the longitudinal extension of the elastic portion 20G.

The presence of the opening Ap particularly defines two opposite portions in the elastic portion 20G which are able to move close and away according to a transversal direction, that is orthogonal to the longitudinal development axis HH, corresponding to the direction x of the local reference of the figure.

Preferably, the elastic stopper 21 has a symmetrical shape, so as to be able to provide a contrast action to a movement of the contact probe 20 with respect to a guide hole in which it is housed regardless of the bending direction of the predeformed shape thereof or without a pair of guides which performs an offset thereof, as it occurs in the known solutions, so as to guarantee a correct operation of a contact head which comprises said probes during testing and cleaning operations, also when the probe head is released from the test equipment.

It is underlined that the elasticity of the elastic stopper 21 furthermore advantageously allows the passage of the contact probe 20 into a respective guide hole during the assembly operations, as well as the extraction thereof by an operator during possible maintenance operations which require for example the removal and substitution of the same contact probe 20, anyway guaranteeing a correct holding even when the probe head which houses it is not in contact pressing onto a device under test or with a board of a test equipment, said elastic stopper 21 being able to efficiently contrast the movement of the contact probe 20 due to the effect of the force of gravity when the probe head is separated by the device under test or disassociated from the test equipment, as well as in presence of other transversal forces, such as during cleaning operations which are normally carried out by air jets.

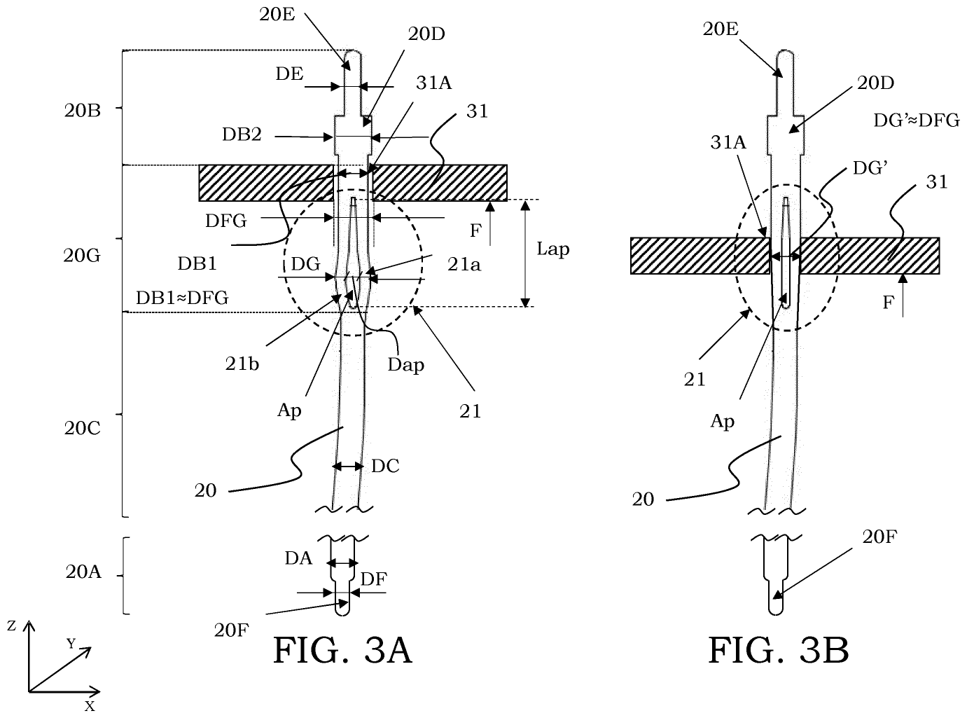

More in particular, as schematically shown in the enlargement of FIG. 3A, said elastic stopper 21 is provided in the elastic portion 20G of the contact probe 20, by a drop-shaped opening Ap, that is with increasing dimensions along the elastic portion 20G towards the probe body 20C and a maximum opening value indicated as opening diameter Dap having a value comprised between 10 μm and 30 μm and a length Lap which is substantially equal to the length LG of the elastic portion in which the elastic stopper 21 is provided. The elastic stopper 21 thus substantially has the shape of a needle eye, the presence of the drop-shaped opening Ap defining two opposite portions in the elastic portion 20G, that is a first arm 21a and a second arm 21b, which are able to move close or away one another according to the transversal direction x.

More in particular, the drop-shaped opening Ap is sized so as to enlarge the elastic portion 20G up to dimensions greater than a guide hole made in a guide of a probe head which houses the contact probe 20, in particular an upper guide hole of an upper guide 31 above the elastic stopper 21. In other words, the elastic stopper 21 has a transversal diameter DG greater than a diameter DGF of an upper guide hole 31A made in the upper guide 31 and adapted to house the contact probe 20.

Thereby, the elastic stopper 21 is able to prevent or at least hinder the movement of the contact probe 20, once inserted in the probe head, upwards that is according to the direction z, considering the local reference of the figure, as will be better explained in the following, when the contact probe 20 is subjected to forces according to the direction z which are comparable to the force of gravity, that is in the normal working conditions of the probe head which houses the contact probe 20, also when not in test conditions and thus non resting onto a device under test, but also to transversal forces, that is in the direction x, that is in cleaning conditions made by air jets, as usual in the field.

In a preferred embodiment, as illustrated in FIG. 3A, the contact tip 20F has a transversal diameter DF reduced with respect to a transversal diameter DA of a remaining part of the first end portion 20A, transversal diameter meaning a maximum transversal dimension of a section, even not circular, taken according to a plane orthogonal to the longitudinal development axis HH, that is to the the direction z. In particular, the contact tip 20F has a transversal diameter DF comprised between 20-60%, preferably equal to 50% of the diameter DA of the first end portion 20A.

Similarly, the contact head 20E has a transversal diameter DE reduced with respect to a transversal diameter DB1 of a remaining part of the second end portion 20B. In particular, the contact head 20E has a transversal diameter DE comprised between 20-60%, preferably equal to 50% of the transversal diameter DB1 of the second end portion 20B.

By suitably dimensioning the lengths LA, LB of the contact tip 20F and of the contact head 20E, respectively, it is possible to increase the service life of the contact probes 20 which are so made and thus of the probe head which comprises then, said reduced portions which are substantially cylindrical in shape can wear out because of the effect of the touches on the contact pads without changing the shape of the transversal section thereof and thus the parameters which define the mechanical and electronic contact of the probes and the respective pad. This feature is particularly advantageous for the contact tips 20F which, in addition to the wear connected to the contact with the pads of the device under test, are also subjected to cleaning operations on abrasive cloths which further increase the wear thereof.

Furthermore, the presence of the contact tip 20F with reduced dimensions makes the contact probe 20 suitable for testing a device under test with contact pads with reduced area.

Suitably, the second end portion 20B is also provided with an enlarged portion 20D having a transversal diameter DB2 greater than the transversal diameter DB1 of the second end portion 20B outside said enlarged portion 20D (DB2>DB1). More in particular, the transversal diameter DB2 of the enlarged portion 20D is chosen so as to be greater than the diameter DGF of the upper guide hole 31A in which the contact probe 20 is housed (DB2>DFG), said enlarged portion 20D preventing a movement of the contact probe 20, downwards, in a direction opposite with respect to the direction z of the local reference of the figure.

Advantageously according to the present invention, the elastic stopper 21 is able to squash itself, moving the first arm 21a and the second arm 21b close to each other until the transversal diameter DG thereof reaches dimensions DG′ corresponding to those of the diameter DFG of the upper guide hole 31A in which the contact probe 20 is housed (DG′≈DFG), so as to allow the passage also of the elastic portion 20G through said upper guide hole, as schematically shown in FIG. 3B. In these conditions, the opening Ap can reduce to null and the first arm 21a can rest onto the second arm 21b. It is thus possible, applying suitable tensile forces to the contact probe 20 which are able to overcome the elasticity of the arms 21a and 21b of the elastic stopper 21, to extract the contact probe 20 from the probe head in which it was assembled, allowing for example the substitution thereof. Such tensile forces are in particular upwards, that is according to the direction z of the local reference of the figures.

In other words, the elastic stopper 21 is elastically deformable between a first condition in which it has a transversal diameter DG greater than the transversal diameter DC of the probe body 20C and it is able to carry out a contrast action to a movement of the contact probe 20 with respect to a guide hole of an upper guide in which the probe is housed and a second working condition in which it has a transversal diameter DG′ which substantially corresponds to the transversal diameter DC of the probe body 20C and it is able to pass in the guide hole, “substantially corresponding” meaning that the difference between said diameters is ±20%. The first working condition is thus a normal working condition, that is the test of a device under test carried out by the probe head which comprises the contact probes 20, said probes being in a pressing contact onto the pads of the device under test or the normal cleaning operations of said probe head, the transversal dimensions of the elastic stopper 21 contrasting possible upwards movements of the contact probe 20, while the second working condition corresponds for example to maintenance or assembly operations, when the contact probes 20 are made to pass through the guide holes.

According to an alternative embodiment not represented in the figure, the contact probe 20 can also comprise an elastic stopper 21 made by an opening with a shape which is non-symmetrical with respect to the longitudinal development axis HH thereof, only one of the arms defined by said asymmetrical opening protruding with respect to a side wall of the contact probe 20 so as to come into contrast with the upper guide above said elastic stopper 21.

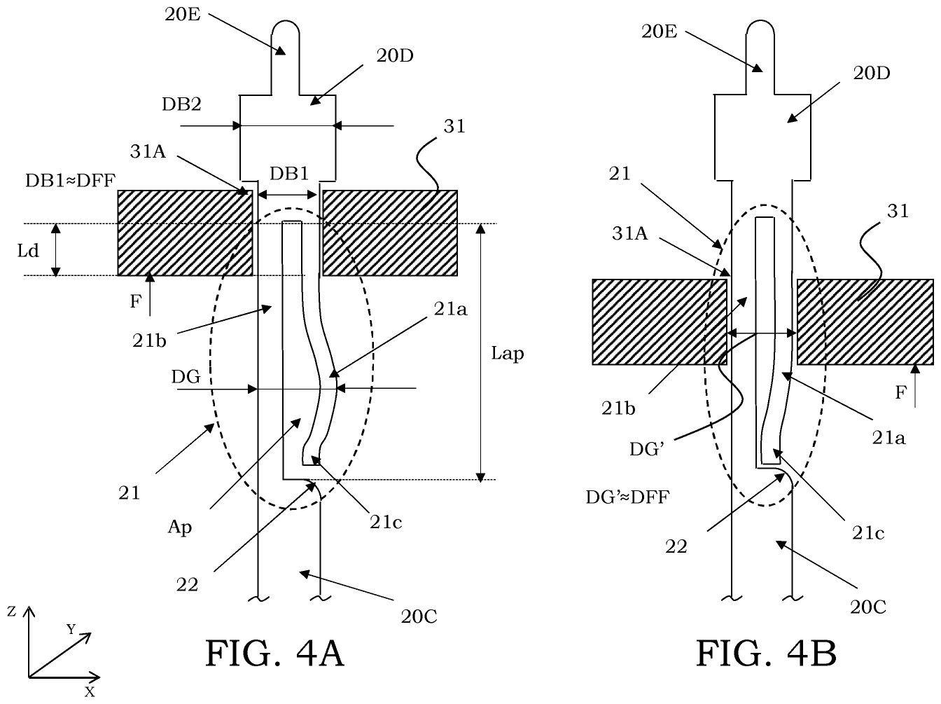

According to another embodiment variation which is schematically illustrated in FIG. 4A, the elastic stopper 21 comprises an opening Ap with a non-symmetrical shape and which extends also at the first arm 21a, said first arm 21a thus having a free end 21c which faces a rounded portion 22 of the probe body 20C under said elastic stopper 21. According to said variation, only the first arm 21a protrudes with respect to a side wall of the contact probe 20 and is adapted to come into contrast with the upper guide 31 which houses said probe, said first arm 21a with free end 21c being the deformable portion of the elastic stopper 21.

Suitably, when the contact probe 20 is housed in the upper guide hole 31A, the opening Ap is inserted for a length Ld in said upper guide hole 31A, the first arm 21a being spaced apart from the second arm 21b and protruding with respect to the side wall of the contact probe 20 after said length Ld. The length Ld is preferably equal to 20-30% of the overall length Lap of the opening Ap.

More in particular, in rest conditions after assembly, the point of maximum side extension of the first arm 21a is anyway not in contact with the upper guide 31, so as to guarantee a correct transmission of the force on the contact head 20E of the contact probe 20 during the pressing contact of the contact tip 20F onto a pad of a device under test.

Also in this case, the elastic stopper 21 can be squashed, moving the first arm 21a and the second arm 21b close to each other until the transversal diameter DG reaches dimensions DG′ corresponding to those of the diameter DFG of the upper guide hole 31A in which the contact probe 20 is housed (DG′≈DFG), so as to allow the passage thereof into the upper guide hole 31A, as schematically shown in FIG. 4B.

It is underlined that in any case the free end 21c of the first arm 21a does not rest onto the rounded portion 22 of the probe body 20C, so as to avoid any plastic deformation of said first arm 21a.

According to a further alternative embodiment illustrated in Figure the opening Ap has a substantially oval shape, still adapted to provide a first arm 21a and a second arm 21b which are substantially equal, symmetrical and contiguous and are able to be moved close in order to let the elastic stopper 21 pass through an upper guide hole which houses the contact probe 20. Such alternative embodiment has the advantage to be totally symmetrical and to reduce possible stress points in the elastic portion 20G where the opening Ap is made.

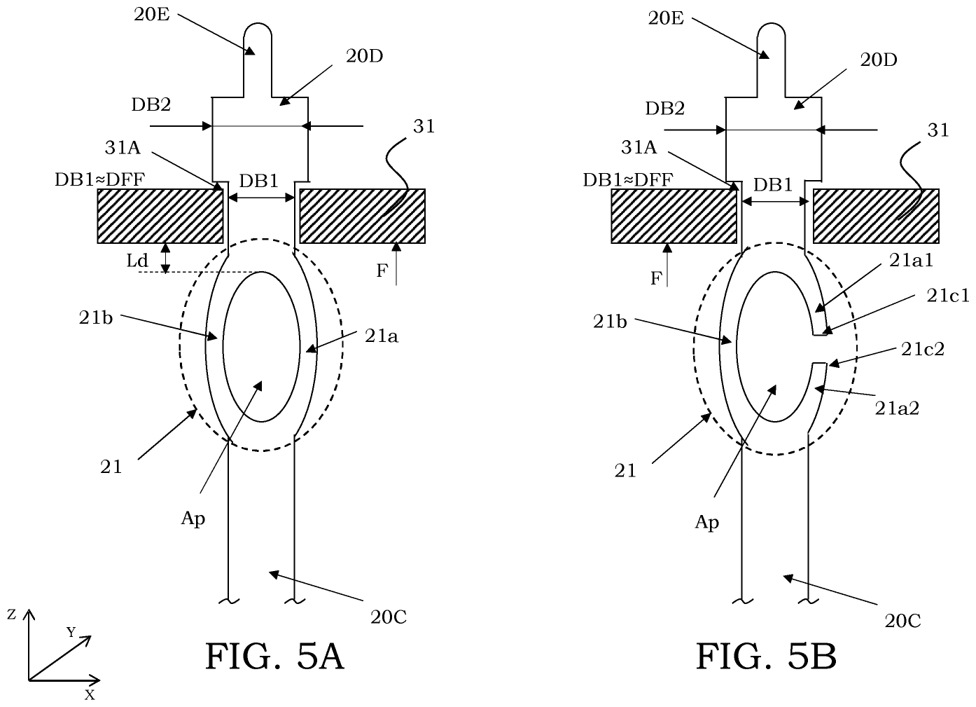

Furthermore, the opening Ap with a substantially oval shape can be interrupted for example at the first arm, providing a first portion 21a1 of first arm having a first free end 21c1 and a second portion 21a2 of first arm having a second free end 21c2, the elastic stopper 21 being in such case substantially C-shaped, as schematically shown in FIG. 5B.

According to this alternative embodiment, when the contact probe 20 is in contact pressing onto a contact pad of a device under test, the elastic stopper 21 can more easily deform in the direction z, in particular closing the C at the free ends 21c1 and 21c2 of the portions 21a1 and 21a2 of the first arm.

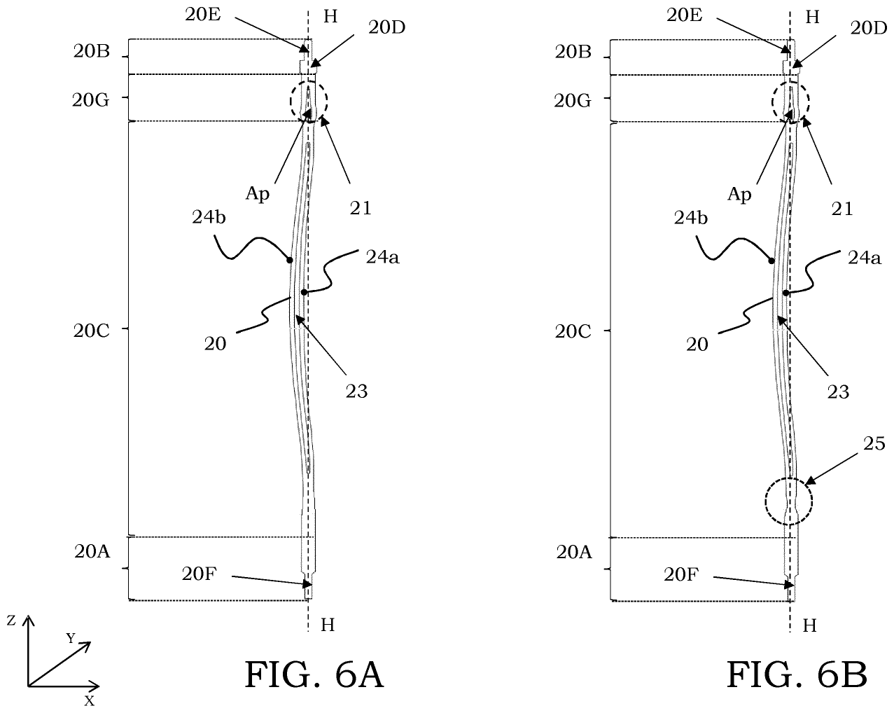

To improve the elasticity of the contact probes 20, it is provided a further opening 23, which extends along the probe body 20C, being so formed by at least one first longitudinal arm 24a and a second longitudinal arm 24b, which are substantially parallel to each other and extended along the direction z, and are separated by said opening 23, as schematically illustrated in FIG. 6A.

It is obviously possible to consider contact probes having a probe body 20C crossed by a plurality of opening 23 and thus provided with more than two longitudinal arms substantially extended along the direction z.

The contact probe 20 can further comprise a portion with reduced section which provides a flexing neck 25 positioned in the probe body 20C at the first end portion 20A, as schematically shown in FIG. 6B. Said flexing neck 25 is able to further improve the elasticity of the contact probe 20, at a section of the same subjected to high stresses, more in particular a section which is contiguous to a junction point of the longitudinal arms.

More in particular, said flexing neck 25 has a section reduced of 30-60% with respect to a section of the probe body 20C, more preferably equal to 50% of the section of the probe body 20C.

In the embodiment illustrated in FIG. 6B, the flexing neck 25 is preferably arranged at the centre of the contact probe 20, in a concentric way with respect the first end portion 20A, along the direction z and is obtained by a removal of material in a symmetric way between at least two opposite sides of the contact probe 20, so as not to negatively affect the bending mechanism of the contact probe 20 and the scrub of the contact tip 20F thereof.

Although the embodiment illustrated in FIG. 6B shows a contact probe 20 provided both with the further opening 23 and with the flexing neck 25 it is also possible to provide the same so as to comprise only the flexing neck 25.

The present invention also refers to a probe head of the type with vertical probes, only comprising a pair of guides provided with housing holes of a plurality of contact probes made as above illustrated.

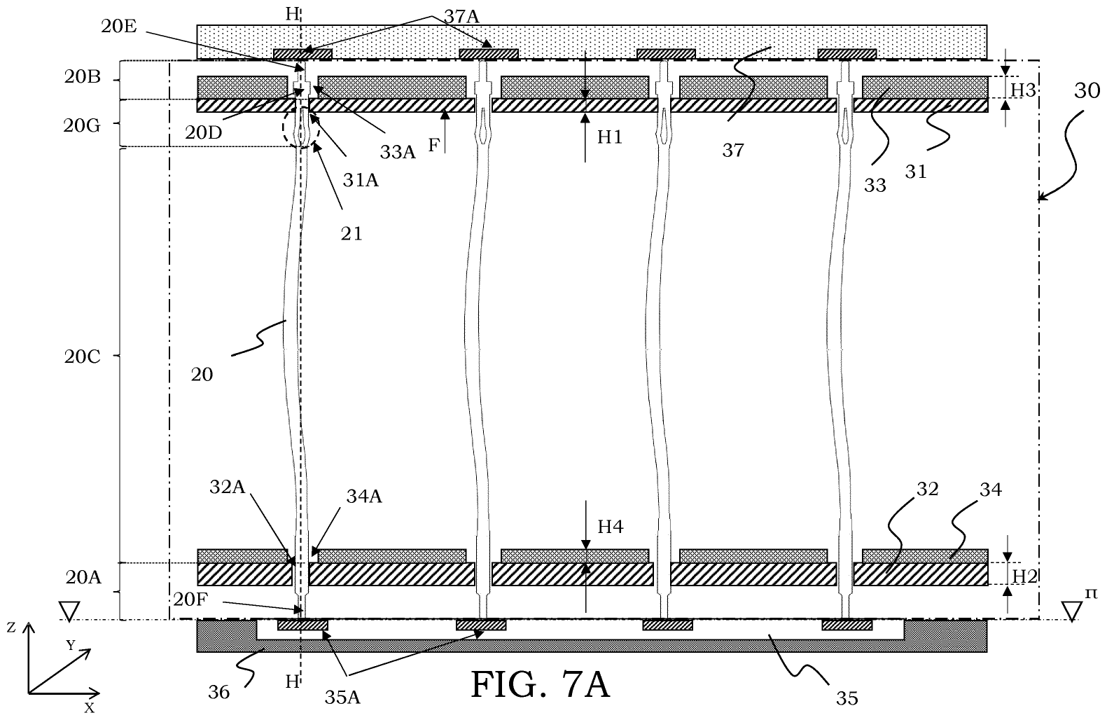

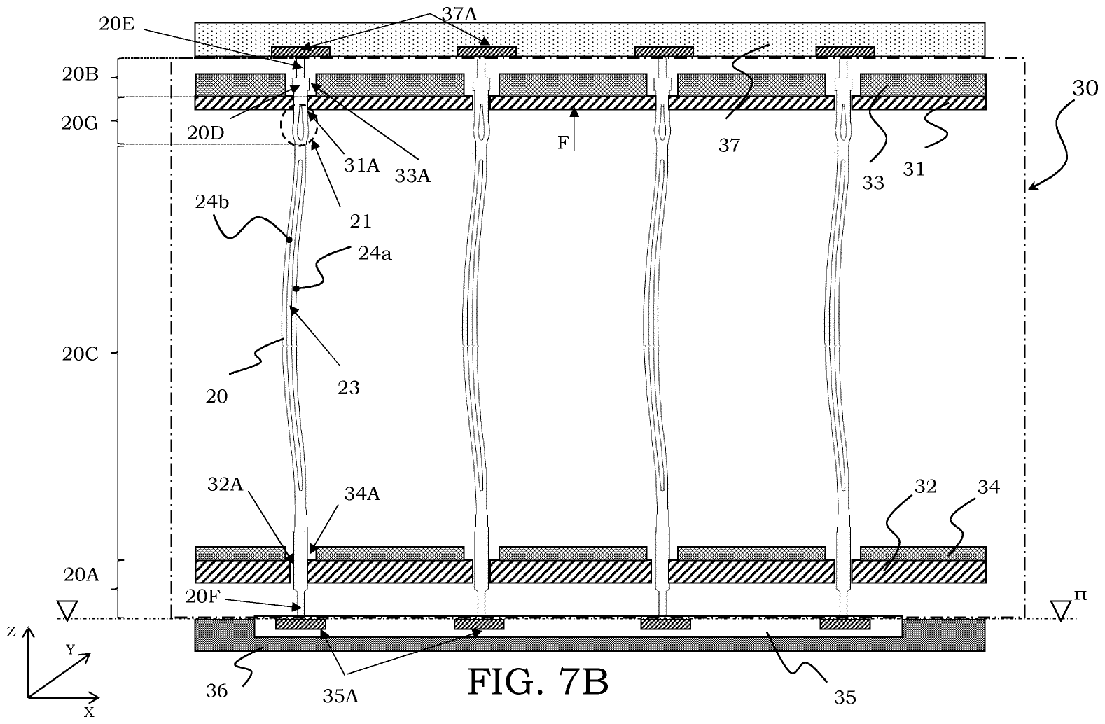

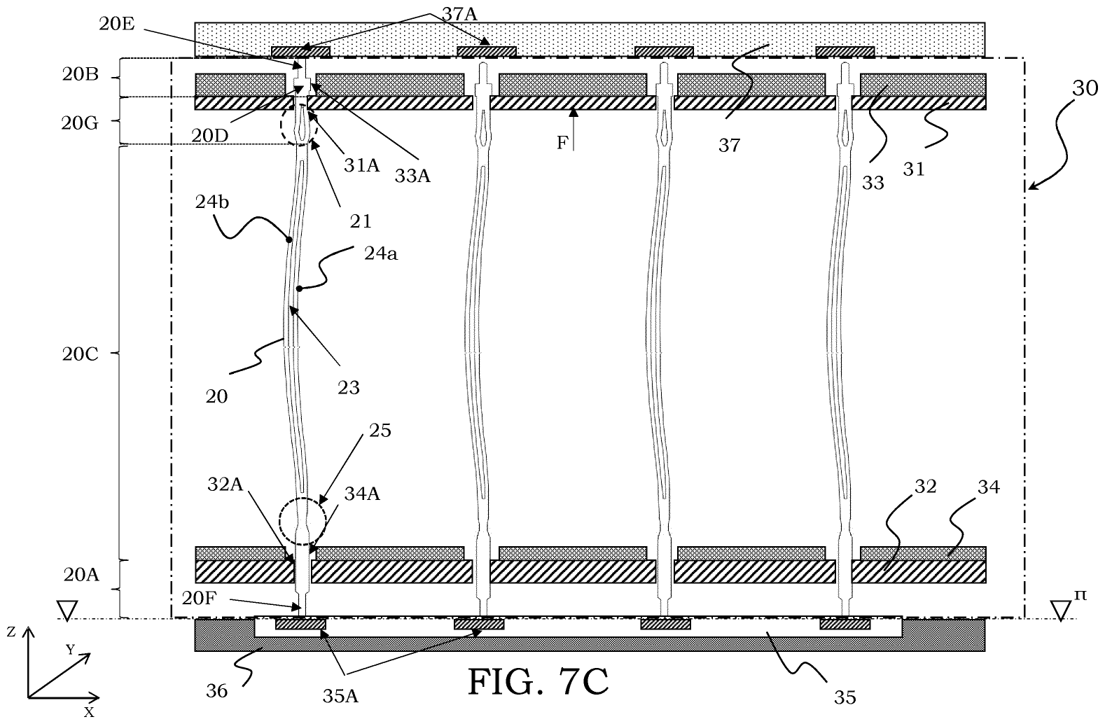

More in particular, referring to FIG. 7A, it is described a probe head 30 comprising a plurality of probes made according to the embodiment illustrated in FIG. 2, that is contact probes which are predeformed to a bow and provided with an elastic stopper 21.

The probe head 30 comprises a first plate-shaped guide or upper guide 31, commonly indicated as upper die, provided with suitable upper guide holes 31A for housing the contact probes 20, as well as a second plate-shaped guide or lower guide 32, commonly indicated as lower die, also provided with suitable lower guide holes 32A for housing the contact probes 20. As seen in connection to the prior art, the upper guide 31 and the lower guide 32 are spaced apart from each other so as to define an air gap between them where the contact probes 20 are free to bend during the pressing contact of the contact tip portions 20F thereof onto a contact pad 35A of a device under test 35 integrated on a semiconductor wafer 36, the corresponding contact heads 20E abutting onto contact pads 37A of an interface board 37 with the test equipment of which the probe head 30 is an end element. As seen in connection with the prior art, said board 37 can be a so-called space transformer.

Suitably, the probe head 30 also comprises an upper frame 33, associated with the upper guide 31 and provided with respective upper openings 33A adapted to house the contact probes 20 and a lower frame 34, associated with the lower guide 32 and also provided with lower openings 34A for housing the contact probes 20. Preferably, the upper frame 33 and the lower frame 34 are ceramic or metallic elements.

More in particular, the upper frame 33 is fixedly connected to the upper guide 31 thanks to the use of connecting elements such as screws, pins or elastic films and analogously the lower frame 34 is fixedly connected to the lower guide 32 still by connecting elements such as screws, pins or elastic films. The upper frame 33 and the lower frame 34 are thereby integral with the upper guide 21 and the lower guide 32, respectively, and act as structural reinforcement elements thereof, as well as alignment instrument of the contact probes 20 during assembly of the probe head 30. It is thereby possible to use guides, preferably ceramic, with reduced thicknesses which simplify the sliding of the contact probes 20 inside the holes thereof.

As shown in FIG. 7A, the contact probe 20 is housed or integrated in the probe head 30 such that the second end portion 20B thereof is inserted in an upper guide hole 31A of the upper guide 31 with the enlarged portion 20D abutting with the undercut wall thereof onto an upper face of said upper guide 31, that is the face of the upper guide 31 facing the upper frame 33, thereby acting as holding element of the contact probe 20 to prevent the movement thereof downwards, in a opposite direction z of the local reference of FIG. 7A.

In particular, the upper guide hole 31A of the upper guide 31 is dimensioned so as to house the second end portion 20B under the enlarged portion 20D with clearance but to prevent the passage of said enlarged portion 20D, while the upper opening 33A of the upper frame 33 has dimensions adapted to house both the enlarged portion 20D and the contact head 20E of the contact probe 20.

Furthermore, advantageously according to the invention, the contact probe 20 is housed in the probe head 30 such that the elastic stopper 21 thereof is positioned under the upper guide hole 31A of the upper guide 31, so as to prevent or at least hinder a movement of the contact probe 20 upwards, that is according to the direction z of the local reference of FIG. 7A. Thereby, the elastic stopper 21 is positioned near the upper guide 31, near meaning that the elastic stopper 21 extends starting from a lower face of the upper guide downwards, that is in a direction opposite the direction z of the local reference of FIG. 7A.

The contact probe 20 further has the first end portion 20A housed in the lower guide hole 32A of the lower guide 32, dimensioned so as to house said first end portion 20A with clearance, while the contact tip 20F protrudes under the lower guide 32 towards the device under test 35 so as to abut onto a contact pad 35A thereof.

The upper guide 31 and the lower guide 32 as well as the upper frame 33 and the lower frame 34 are parallel to each other and extend along a reference plane n, which is the same along which also the semiconductor wafer 36 and the device under test 35 as well as the board 37 of the test equipment develop.

Furthermore, the lower guide 32 is suitably dimensioned so as to assist the movement of the contact probes 20 in overdrive during the testing operations when said probes abut onto the device under test 35.

More in particular, the lower guide 32 has a thickness H2 along the direction z greater than the thickness H1 of the upper guide 31, preferably equal to 1.8-2 times the thickness H1 of the upper guide 31. In a preferred embodiment, the upper guide 31 has a thickness H1 which varies from 0.100 mm to 0.150 mm, preferably equal to 0.125 mm while the lower guide 32 has a thickness H2 which varies from 0.150 mm to 0.300 mm, preferably equal to 0.254 mm.

Suitably according to the embodiment illustrated in FIG. 7A, the upper frame 33 has a thickness H3 comparable, preferably equal, to the thickness H2 of the lower guide 32 and the lower frame 34 has a thickness H4 comparable, preferably equal to the thickness H1 of the upper guide 31, comparable meaning that the difference between the two thicknesses is ±20%.

Thereby, the assembly of the upper guide 31 and the upper frame 33 has a thickness comparable, preferably equal to the assembly of the lower guide 32 and of the lower frame 34, so as to guarantee a dynamic and elastic symmetry of the contact probe 20 and of the probe head 30 as a whole.

It is also possible to provide the probe head 30 housing therein a plurality of contact probes 20 made according to the embodiment of FIG. 6A, as schematically illustrated in FIG. 7B.

In such case, the contact probes 20 also comprise respective longitudinal openings 23 provided in the probe body 20C at the air gap between the upper guide 31 and the lower guide 32, said longitudinal openings 23 defining in the probe body 20C respective longitudinal arms 24a, 24b which improve the elasticity of the probes as a whole, in particular preventing the breakage of the same probes or of the contact pads of the device under test also in the case of short probes adapted to radiofrequency applications.

Furthermore, as schematically illustrated in FIG. 7C, the contact probes 20 can also be provided with respective flexing necks 25, which are suitably positioned at the end of the probe body 20C at the lower frame 34, possibly housed in the lower openings 34A of said lower frame 34, further improving the bending of the contact probes 20, so as to lower the risks of breakage of the same probes or of the pads of the device under test.

To conclude, the contact probe provided with at least one elastic stopper is adapted to be used in a probe head comprising only one upper guide and only one lower guide, said elastic stopper guaranteeing a correct holding of the probe inside said head, while removing the need to increase the diameter of the guide holes which house the probe, since said stopper can be passed through guide holes having diameters which are substantially corresponding to those of the probes by virtue of the elasticity thereof.

In particular, advantageously according to the present invention, the elasticity of the elastic stopper allows the passage of the contact probe into a respective guide hole during the assembly operations, as well as the extraction thereof by an operator during possible maintenance operations which require for example the removal or substitution of the same probe, still guaranteeing a correct holding also when the probe head which houses it is not in contact pressing onto a device under test or with a board of a test equipment thanks to the contrast made by said elastic stopper, which is able to prevent the movement of the probe because of the effect of gravity when the probe head is separated by the device under test or disassociated from the test equipment, as well as in presence of other transversal forces, such as during cleaning operations which are normally carried out by air jets.

Suitably, said elastic stopper is made so as to protrude with respect to at least one of the side walls of the probes, preferably with respect to both the side walls, so as to come into contrast with a guide above it to prevent displacements of the probes during the normal testing, maintenance or cleaning operations of the probe head which comprises them.

The contact probes can be furthermore predeformed so as to ease the uniform bending of the same when they are housed in a corresponding probe head, in particular during the contact pressing onto a device under test during the testing operations carried out by the probe head, so as to reduce to the minimum the risk of contact between adjacent probes, also without a pair of shifted guides such as in the known solutions.

Preferably, the probes comprise end contact portions having reduced transversal diameters and suitable lengths which are able to allow a wear thereof due to the effect of the testing or cleaning operations, increasing the service life of the probe head as a whole, in addition to allowing the testing of pads with reduced dimensions.

Suitably, the elastic stopper can be provided in a very simple way by an opening formed in the probe body and adapted to define at least one pair of portions of said body which are able to move close or away with respect to each other. The elastic stopper can also have an open shape at one of the arms thereof, which simplifies the deformation thereof when the contact probe is longitudinally subjected to the force of gravity or other transversal forces.

It is furthermore possible to provide the probes with openings made in the probe body thereof to form a plurality of longitudinal arms and/or of flexing necks so as to improve the elasticity of the probes as a whole.

It is thereby possible to provide the probes with particularly reduced overall lengths and thus adapted to applications in the more recent technologies, for example for very high-frequency applications using only a pair of guides, anyway guaranteeing the correct holding of the probes inside them.

The contact probe according to the present invention thereby allows to also overcome the drawbacks of the known solutions comprising double guides to provide an offset of the probes, which, in particular in presence of a great number of contact probes, can convey onto the device under test a transversal force which is able to cause undesired displacements thereof.

Obviously, a person skilled in the art, in order to meet contingent and specific requirements, may make to the contact probe and to the probe head above described numerous modifications and variations, all included in the scope of protection of the invention as defined by the following claims.

In particular, it is possible to consider any shape for the opening which provides the elastic stopper, in addition to the use of possible flexible materials for filling the same, as well as any number of longitudinal openings to form any number of arms in the probe body.

Finally, it is possible to provide the contact probe of the present invention with further expedients, such as other geometrical configurations of the contact tip and head portions or the presence of coating films.

1.-20. (canceled)

21. A contact probe having:
a first end portion which ends with a contact tip adapted to abut onto a contact pad of a device under test;
a second end portion which ends with a contact head adapted to abut onto a contact pad of a board of a test equipment;
a probe body extended between the first end portion and the second end portion according to a longitudinal development axis and having a transversal diameter; and
an elastic stopper provided in an elastic portion of the probe body arranged contiguous to the second end portion and having a transversal diameter,
wherein the elastic stopper is elastically deformable between a first working condition, in which the transversal diameter of the elastic stopper is greater than the transversal diameter of the probe body, and a second working condition in which the transversal diameter of the elastic stopper is equal to the transversal diameter of the probe body,
wherein the transversal diameter means a maximum transversal dimension of a section, even not circular, taken according to a plane orthogonal to the longitudinal development axis.

22. The contact probe of claim 21, wherein the elastic stopper includes an opening which is provided in the elastic portion of the probe body and defines therein two opposite arms which are able to move close and away according to a transversal direction orthogonal to the longitudinal development axis.

23. The contact probe of claim 22, wherein the opening is drop-shaped with decreasing dimensions along the elastic portion of the probe body towards the second end portion.

24. The contact probe of claim 22, wherein the opening extends along the elastic portion of the probe body over a length equal to a length of the elastic portion.

25. The contact probe of claim 22, wherein the opening has a non-symmetrical shape adapted to define an arm protruding with respect to a side wall of the contact probe.

26. The contact probe of claim 25, wherein the opening extends in correspondence of an arm which has a free end.

27. The contact probe of claim 26, wherein the free end of the arm faces a rounded portion of the probe body.

28. The contact probe of claim 22, wherein the opening has an oval shape adapted to define a first arm and a second arm which are equal, symmetrical and contiguous, protruding from opposite walls of the contact probe.

29. The contact probe of claim 22, wherein the opening has an oval shape interrupted at an arm and adapted to define a first portion therein having a first free end and a second portion having a second free end, the elastic stopper being C-shaped.

30. The contact probe of claim 21, wherein the probe body has a predeformed shape with a curvilinear configuration comprising a bow in rest conditions, when the contact probe is not in contact pressing onto a contact pad of a device under test, according to an arc having a value ranging between 1° and 5°.

31. The contact probe of claim 21, further comprising a further opening, which extends along the probe body, being so formed by a first longitudinal arm and a second longitudinal arm, parallel to each other and extended along the longitudinal development axis, separated by the further opening.

32. The contact probe of claim 21, further comprising a portion with reduced section which forms a flexing neck positioned in the probe body in correspondence of the first end portion.

33. The contact probe according to claim 21, wherein the contact tip has a reduced transversal diameter of a diameter of a remaining part of the first end portion and a length according to the longitudinal development axis of between 300 μm and 600 μm.

34. The contact probe according to claim 21, wherein the contact head has a reduced transversal diameter of a diameter of a remaining part of the second end portion and a length according to the longitudinal development axis of between 100 μm and 400 μm.

35. The contact probe according to claim 21, wherein the contact tip has a reduced transversal diameter of a diameter of a remaining part of the first end portion and a length according to the longitudinal development axis between 300 μm and 600 μm and the contact head has a reduced transversal diameter of a diameter of a remaining part of the second end portion and a length according to the longitudinal development axis of between 100 μm and 400 μm.

36. The contact probe of claim 21, wherein the second end portion comprises an enlarged portion, having a transversal diameter greater than a diameter of a remaining part of the second end portion.

37. A probe head for verifying the functionality of a device under test comprising:
a plurality of contact probes;
a single upper guide provided with upper guide holes; and
a single lower guide provided with lower guide holes, the upper guide holes and lower guide holes being adapted to house the plurality of contact probes;
wherein each of the plurality of contact probes has:
a first end portion which ends with a contact tip adapted to abut onto a contact pad of a device under test;
a second end portion which ends with a contact head adapted to abut onto a contact pad of a board of a test equipment;
a probe body extended between the first end portion and the second end portion according to a longitudinal development axis and having a transversal diameter; and
an elastic stopper provided in an elastic portion of the probe body arranged contiguous to the second end portion and having a transversal diameter, wherein the elastic stopper is elastically deformable between a first working condition, in which the transversal diameter of the elastic stopper is greater than the transversal diameter of the probe body, and a second working condition in which the transversal diameter of the elastic stopper is equal to the transversal diameter of the probe body, wherein the term transversal diameter means maximum transversal dimension of a section, even not circular, taken according to a plane orthogonal to the longitudinal development axis; and
wherein the elastic stopper is positioned between the single upper guide and the single lower guide, near the single upper guide.

38. The probe head of claim 37, further comprising an upper frame, associated with the single upper guide and provided with respective upper openings adapted to house the contact probes and a lower frame, associated to the single lower guide and provided with respective lower openings adapted to house the contact probes.

39. The probe head of claim 38, wherein the upper openings of the upper frame house the second end portions of the contact probes with clearance and wherein the lower openings of the lower frame house the first end portions of the contact probes with clearance, the contact tips projecting starting therefrom towards the device under test.

40. The probe head of claim 38, wherein the single lower guide has a thickness along said longitudinal development axis greater than a thickness of the single upper guide and wherein the upper frame has a thickness comparable to the thickness of the single lower guide and the lower frame has a thickness comparable to the thickness of the single upper guide, wherein comparable has the meaning that the difference between the thicknesses is ±20%.
